(19) United States
(12) Patent Application Publication
(10) Pub. No.: US 2015/0085592 A1
(43) Pub. Date: Mar. 26, 2015

(54) Bit-Line Discharge Assistance in Memory Devices

(71) Applicant: LSI Corporation, San Jose, CA (US)

(72) Inventors: Dharmendra Kumar Rai, Utter Pradesh (IN); Rahul Sahu, Utter Pradesh (IN)

(73) Assignee: LSI Corporation, San Jose, CA (US)

(21) Appl. No.: 14/070,836

(22) Filed: Nov. 4, 2013

(30) Foreign Application Priority Data
Sep. 20, 2013 (IN) 4257/CHE/2013

(51) Int. Cl. G11C 7/12

(52) U.S. Cl. CPC G11C 7/12
USPC 365/203

(57) ABSTRACT

One embodiment is an apparatus that has a memory array, a discharge device, and a discharge assistance controller. The memory array has memory cells arranged in at least one column that is coupled to a read bit line, and the discharge device is configured to provide discharge assistance to the read bit line. The discharge assistance controller is configured to modify duration of the discharge assistance in correlation with capacitance of the read bit line.

### FIELD OF INVENTION

Embodiments of the invention relates to the storage and retrieval of data, and, more specifically but not exclusively, to reading data from transistor-implemented memory devices such as read-only memory (ROM) devices and random-access memory (RAM) devices.

### BACKGROUND

In conventional transistor-implemented memory, such as that implemented using RAM or ROM technology, bits of information are stored in an array of bit cells, where the bit cells are arranged in columns and rows. Such memory may be implemented on chip as in register files or off chip as standalone memory devices. The bit cells in each row are coupled to at least one read word line, and the bit cells in each column are coupled to at least one read bit line. The following description applies to exemplary memory having only one read word line per row and only one read bit line per column. Typically, when conditions are established to perform a read operation for a particular bit cell, the bit line coupled to the bit cell is pre-charged. When a read operation is performed, a pulse is applied to the read word line coupled to the bit cell, and the read bit line is either discharged or not discharged, depending on the bit value stored in the bit cell. For example, in at least some implementations in which the read bit line is pre-charged high, the read bit line is discharged when a value of “1” is stored and not discharged when a value of “0” is stored. The bit value is then detected using a sense amplifier.

In the design of a memory device, the number of rows of bit cells in the memory array can have a relatively significant effect on the reading characteristics of the memory device. As the number of rows is increased, the accumulated capacitance of each read bit line increases, which, in turn, increases the duration of time that it takes for each read bit line to discharge. Further, as the discharge duration of each read bit line increases, the amount of time that is needed for the corresponding sense amplifier to detect whether a value of “1” or a value of “0” is stored increases. However, increasing the duration of the sensing operation, increases the access time of the memory array, making the memory array less efficient.

### SUMMARY

One embodiment of the invention is an apparatus comprising a memory array, a discharge device, and a discharge assistance controller. The memory array comprises memory cells arranged in at least one column that is coupled to a read bit line. The discharge device is configured to provide discharge assistance to the read bit line. The discharge assistance controller is configured to modify duration of the discharge assistance in correlation with capacitance of the read bit line.

### BRIEF DESCRIPTION OF THE FIGURES

Embodiments of the disclosure will become more fully apparent from the following detailed description, the appended claims, and the accompanying drawings in which like reference numerals identify similar or identical elements.

FIG. 1 shows a simplified block diagram of a memory device according to one embodiment of the disclosure that implements discharge assistance;

FIG. 2 shows a simplified schematic circuit diagram of a bit cell according to one embodiment of the disclosure that may be used to implement each bit cell in the memory array of FIG. 1;

FIG. 3 shows a simplified schematic circuit diagram of a sense amplifier according to one embodiment of the disclosure that may be used to implement each sense amplifier in FIG. 1;

FIG. 4 shows a simplified schematic circuit diagram of a discharge assistance controller according to one embodiment of the disclosure that may be used to implement the discharge assistance controller in FIG. 1;

FIG. 5 shows an exemplary timing diagram of a read operation performed by the memory device of FIG. 1 to read a value of “1”; and

FIG. 6 shows an exemplary timing diagram of a read operation performed by the memory device of FIG. 1 to read a value of “0”.

### WRITTEN DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Rather than allowing the duration of the sensing operation to be based directly on the number of rows in the memory array, discharge assistance may be provided to the memory array to ensure that the discharge duration does not become too long. Discharge assistance may be implemented using one or more discharge assistance devices that are (i) coupled to the read-bit lines and (ii) turned on and off as needed to control the discharge durations of the read bit lines. Thus, the amount of time that the one or more discharge assistance devices are turned on may be automatically set based on the number of rows in the memory array to prevent the discharge duration of the read bit lines from becoming too long.

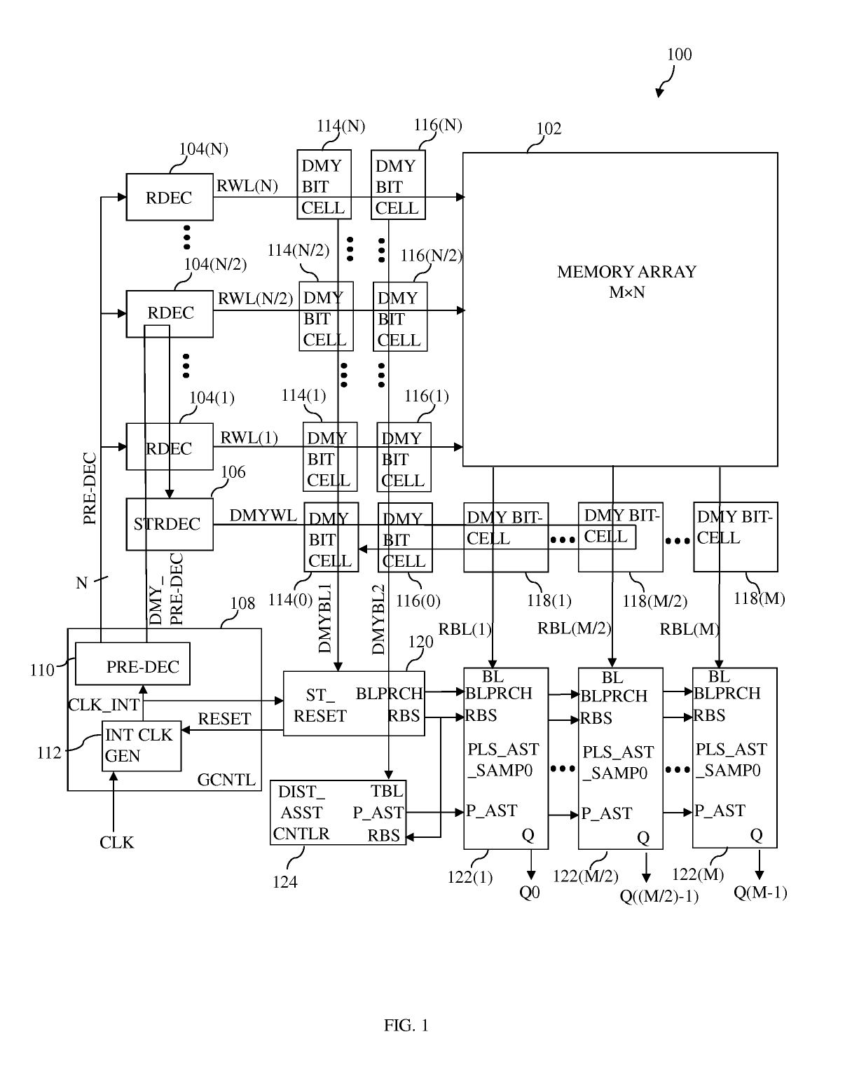

FIG. 1 shows a simplified block diagram of a memory device 100 according to one embodiment of the disclosure that implements discharge assistance. Memory device 100 may be implemented as a stand-alone chip or as memory in an embedded system. When conditions are being established to read a row of memory array 102, self-time reset circuit 120 changes the state of the bit-line pre-charge signal BLPRCH provided to sense amplifiers 122(1)-122(M), and as a result, sense amplifiers 122(1)-122(M) pre-charge their respective one of M read bit lines RBL(1)-RBL(M). When a read operation occurs, internal clock generator 112 of global controller 108 changes the state of the internal clock signal CLK_INT. Based on this change in state, self-time reset circuit 120 changes (i) the state of the bit-line pre-charge signal BLPRCH to terminate the pre-charging and (ii) the state of the read bit-line select RBS signal to enable sensing by the sense amplifiers 122(1)-122(M).

Further, based on the change in state of internal clock signal CLK_INT, pre-decoder 110 partially decodes the address of memory array 102 from which data is to be read (i.e., the read address). The partially-decoded read address is provided via N pre-decode lines PRE-DEC to row decoders 104(1)-104(N). Row decoders 104(1)-104(N) complete the decoding of the partially-decoded read address, and the particular row decoder i corresponding to the current read address drives its corresponding read word line RWL(i) to read data from the bit cells coupled to that read word line.

Upon driving the read word line RWL(i), each read bit line RBL(1)-RBL(M) either discharges or does not discharge, depending on the value of the bit stored in the corresponding bit cell. The state of each read bit line RBL(1)-(M) is sensed by a corresponding sense amplifier 122(1)-122(M), which senses whether or not the read bit line has discharged.

To determine the proper durations of the pulses applied to the read word lines RWL(1)-(N) and the read bit-line select signal RBS, memory device 100 employs dummy circuitry (also referred to as tracking circuitry). In particular, this dummy circuitry has (i) a first dummy bit line DMYBL1 that is configured with dummy bit cells 114(0)-114(N) and (ii) a dummy word line DMYWL that is configured with dummy bit cells 114(0), 116(0), and 118(1)-118(M). Note that dummy bit cell 114(0) is shared between dummy word line DMYWL and first dummy bit line DMYBL1. First dummy bit line DMYBL1 is used as a reference for the timing characteristics of the read bit lines RBL(1)-RBL(M) of memory array 102, and dummy word line DMYWL is used as a reference for the timing characteristics of the read word lines RWL(1)-RWL(N) of memory array 102.

Self-time reset circuit 120 generates the pre-charge signal BLPRCH, the read bit-line select signal RBS, and the reset signal RESET, based on internal clock signal CLK_INT and the signal on first dummy bit line DMYBL1. Methods of generating these signals are not described herein as they are well known.

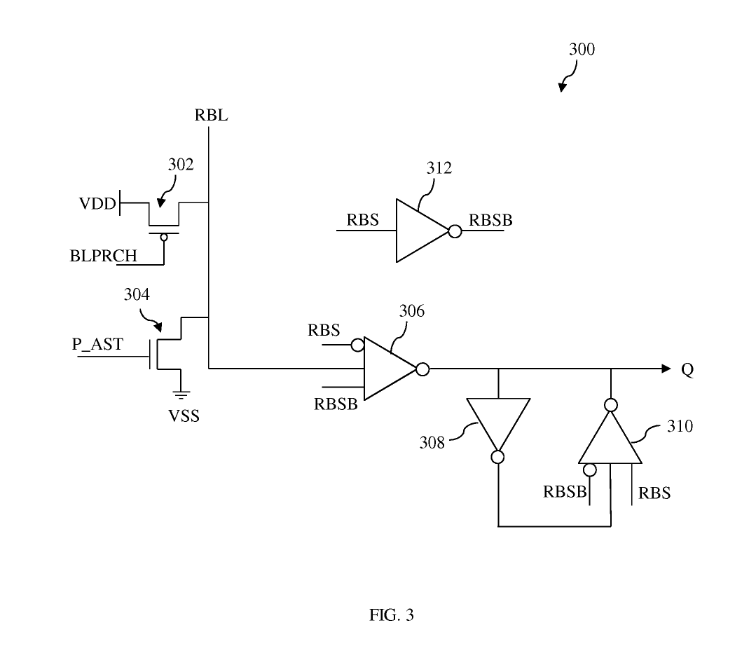

Memory device 100 also comprises discharge assistance circuitry for assisting the discharge of read bit lines RBL(1)-RBL(M). This discharge assistance circuitry is formed from discharge assistance controller 124, a second dummy bit line DMYBL2, and discharge assistance devices that are located in each sense amplifier 122(1)-122(M) (discussed further below in relation to FIG. 3). Second dummy bit line DMYBL2 is configured with dummy bit cells 116(0)-116(N) and, like first dummy bit line DMYBL1, is used as a reference for timing characteristics of the read bit lines RBL(1)-RBL(M) of memory array 102. Note that dummy bit cell 116(0) is shared between dummy word line DMYWL and second dummy bit line DMYBL2.

In operation, discharge assistance controller 124 applies a pulse (herein referred to as “the discharge assistance pulse” or simply “the pulse”) to a pulse-assist signal P_AST when a sensing operation is performed. The pulse turns on the discharge assistance devices in sense amplifiers 122(1)-122(M) to assist in the discharge of read bit lines RBL(1)-RBL(M). The duration of the pulse generated by discharge assistance controller 124, and hence the amount of time that the discharge assistance devices are turned on, varies based on the capacitance of the second dummy bit line DMYBL2. In particular, discharge assistance controller 124 increases the duration of the pulse for higher capacitance levels of the second dummy bit line DMYBL2, and decreases the duration of the pulse for lower capacitance levels of the second dummy bit line DMYBL2.

As described above, the capacitance of the bit lines (including the second dummy bit line DMYBL2) is larger for larger numbers of rows and smaller for smaller numbers of rows. Thus, discharge assistance controller 124 automatically sets the pulse duration (i.e., the amount of time that discharge assistance is provided) based on the number of rows in the memory array such that larger pulse durations correspond to larger numbers of rows, and smaller pulse durations correspond to smaller numbers of rows.

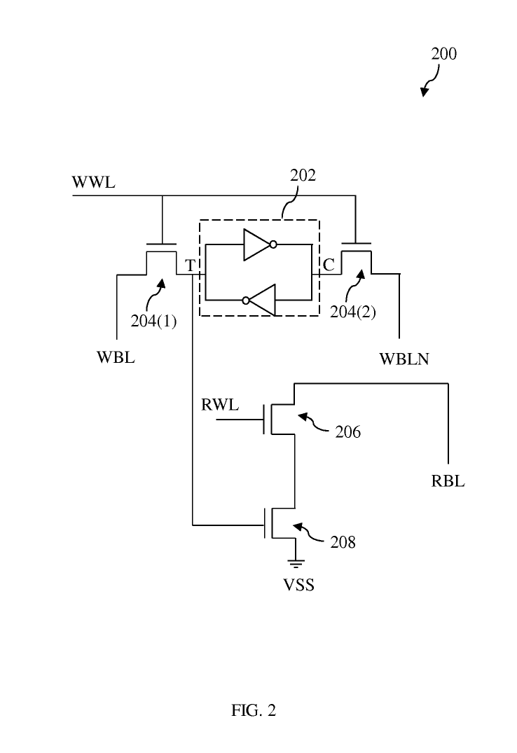

In addition, discharge assistance controller 124 also adapts the duration of the pulse to account for variations in process, voltage, and temperature (PVT) conditions. In slow PVT conditions, the discharge rate of second dummy bit line DMYBL2 is slower, and, in fast PVT conditions, the discharge rate of second dummy bit line DMYBL2 is faster. Discharge assistance controller 124 adapts the pulse duration to increase the pulse duration in slow PVT conditions and decrease the pulse duration in fast PVT conditions. To further understand the operation of memory device 100, consider FIGS. 2-6.

FIG. 2 shows a simplified schematic circuit diagram of a RAM bit cell 200 according to one embodiment of the disclosure that may be used to implement each bit cell in memory array 102. RAM bit cell 200 may also be used to implement dummy bit cells 114(0)-114(N), 116(0)-116(N), and 118(1)-118(M) of FIG. 1. However, in such a case, RAM bit cell 200 may be hard coded to store a zero, and pre-charged, such that the respective dummy bit lines are always discharged during a read operation. Bit cell 200 is a single-ended-read bit cell, meaning that a bit of information is read from bit cell 200 using a single read bit line RBL. In other embodiments, bit cells may have more than one read bit line. Bit cell 200 stores a bit of information using six transistors: four transistors forming a pair of cross-coupled inverters 202 coupled to an N-type transistor 204(1) via true node T and an N-type transistor 204(2) via complement node C. When true node T is high, complement node C is low, and a value of “1” is stored in bit cell 200. When true node T is low, complement node C is high, and a value of “0” is stored in bit cell 200.

Writing to bit cell 200 is performed using a write bit line WBL, a complement write bit line WBLN, and a write word line WWL. The channels of transistors 204(1) and 204(2) are coupled to write bit line WBL and complement write bit line WBLN, respectively, and the gates of transistors 204(1) and 204(2) are coupled to write word line WWL. The operation of writing information to bit cell 200 is not described herein as it is well known.

Reading from bit cell 200 is performed using transistors 206 and 208, read word line RWL, and read bit line RBL. As described above, when conditions are being established to perform a read operation, read bit line RBL is pre-charged to a high value by a corresponding sense amplifier. When the read word line RWL is driven high, transistor 206 turns on. If the value stored at true node T is high (i.e., a value of “1” is stored at true node T), such that transistor 208 is on, then read bit line RBL discharges to low voltage reference VSS. If, on the other hand, the value stored at true node T is low (i.e., a value of “0” is stored at true node T), such that transistor 208 is off, then read bit line RBL does not discharge to low voltage reference VSS.

FIG. 3 shows a simplified schematic circuit diagram of a sense amplifier 300 according to one embodiment of the disclosure that may be used to implement each sense amplifier 122(1)-122(M) of FIG. 1. Sense amplifier 300 is a single-ended sense amplifier, meaning that sense amplifier senses a bit of information from a single read bit line RBL. In alternative embodiments having bit cells with more than one read bit line, sense amplifiers may sense information from more than one read bit line. Sense amplifier 300 has P-type transistor 302, which is used to pre-charge read bit line RBL. When the pre- charge signal BLPRCH, which is provided to the gate of transistor 302, is low, transistor 302 is on, and the read bit line RBL is pre-charged to a high voltage reference VDD through the channel of transistor 302. Before any read word line RWL is driven high, the pre-charge signal BLPRCH is driven high by self-timed reset circuitry (e.g., 120 of FIG. 1) to stop the pre-charging.

When the read bit-line select signal RBS is driven low, complement read bit-line select signal RBSB is driven high by inverter 312 and two things happen. First, tri-state inverter 306 turns on such that tri-state inverter 306 drives output signal Q. Second, tri-state inverter 310, which is cross-coupled to standard inverter 308 to form a latch, turns off, such that output signal Q is permitted to change without restraint. When the read bit line RBL discharges to the trip point of tri-state inverter 306, tri-state inverter 306 drives output signal Q high, indicating that a value of “1” is read. When the read bit line RBL does not discharge to the trip point of tri-state inverter 306, tri-state inverter 306 keeps output signal Q low, indicating that a value of “0” is read. The state of output signal Q is then latched by the latch formed by inverter 308 and tri-state inverter 310 when the read bit-line select signal RBS is driven high.

Sense amplifier 300 also comprises a discharge assistance device, which, in this embodiment, is formed by N-type transistor 304. Transistor 304 is coupled to the read bit line RBL to assist in the discharging of the read bit line RBL. When the discharge assistance controller (e.g., 124 of FIG. 1) drives the pulse-assist signal P_AST high, transistor 304 turns on, and the read bit line RBL partially discharges through the channel of transistor 304 toward a low voltage-reference source VSS (e.g., ground) until the pulse-assist signal P_AST transitions low.

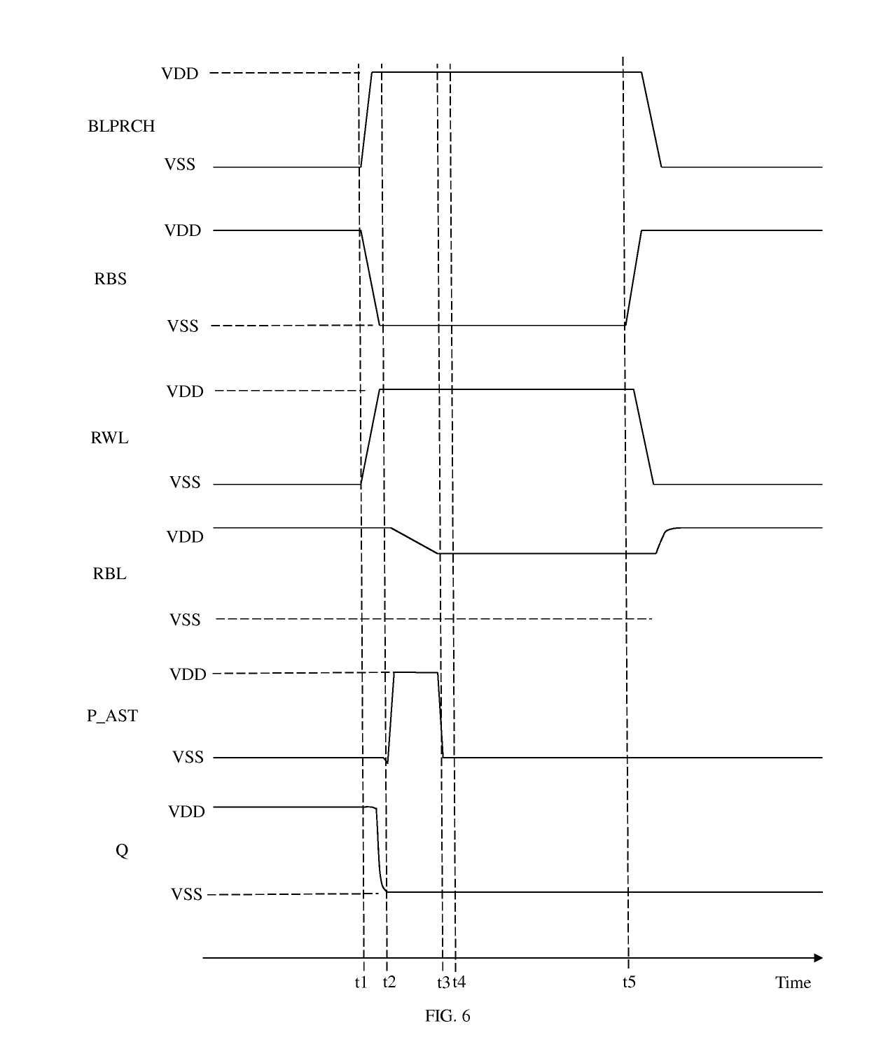

Note that the read bit line RBL partially discharges through transistor 304, regardless of the bit value stored in the bit cell. When a value of “1” is stored in the bit cell, the read bit line RBL is discharged through both transistor 304 and the bit cell (e.g., through transistors 206 and 208 of FIG. 2). When a value of “0” is stored in the bit cell, the read bit line RBL is discharged through transistor 304 only. However, the strength (i.e., size) of transistor 304 and the duration of the pulse applied to pulse-assist signal P_AST are designed such that, when the read bit line RBL is discharged through transistor 304 only, the read bit line RBL will not discharge to the trip point of tri-state inverter 306. As a result, even though some discharge assistance is provided in this case, tri-state inverter 306 will keep output signal Q low. This is illustrated further below in relation to FIG. 6.

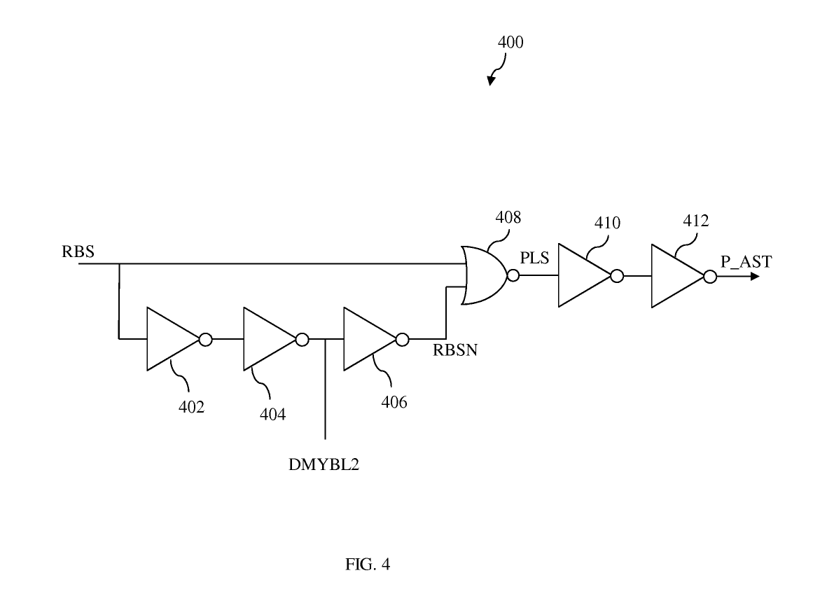

FIG. 4 shows a simplified schematic circuit diagram of a discharge assistance controller 400 according to one embodiment of the disclosure that may be used to implement discharge assistance controller 124 in FIG. 1. Discharge assistance controller 400 has NOR gate 408, which receives (i) the read bit-line select signal RBS from, for example, self-time reset circuit 120 in FIG. 1, and (ii) a complement read bit-line select signal RBSN. The complement read bit-line select signal is generated by applying the read bit-line select signal RBS to an odd number of (e.g., three) series-connected inverters 402, 404, and 406. NOR gate 408 generates a signal PLS that is inverted by inverters 410 and 412 to generate the discharge assist signal P_AST.

Before a read operation is performed, read bit-line select signal RBS is high, and the complement read bit-line select signal RBSN generated by inverters 402, 404, and 406 is low, such that the signal PLS output from NOR gate 408 is low. Further, the second dummy bit line DMYBL2 is driven high (i.e., pre-charged) by inverter 404. When the read bit-line select signal RBS transitions low to begin sensing, there is a delay before the complement read bit-line select signal RBSN transitions high. During this delay, NOR gate 408 generates a pulse on signal PLS, wherein the signal PLS is high.

The duration of the delay, and hence the duration of the pulse, is a function of the delays of inverters 402, 404, and 406 and the capacitance of the second dummy bit line DMYBL2, which is coupled between inverters 404 and 406. As the read bit-line select signal RBS transitions low, the second dummy bit line DMYBL2 is discharged. The discharging of the second dummy bit line DMYBL2, which is a function of the capacitance of the second dummy bit line DMYBL2, delays the inversion of the complement read bit-line select signal RBSN. In at least some embodiments, the transistors forming inverters 402, 404, and 406 are sized such that the duration of the pulse, and hence the delay, is larger for larger capacitive loads of the second dummy bit line DMYBL2 and smaller for smaller capacitive loads of the second dummy bit line DMYBL2. As described above, using the second dummy bit line DMYBL2 as a reference enables discharge assistance controller 400 to set the pulse duration to account for the number of rows in the memory array and the effects of PVT variations on the bit lines.

Further, in at least some embodiments, the discharge assistance circuitry is sized to mimic driving and loading of the read word lines RWL. In such embodiments, inverter 412 is selected to be the same size as the word line drivers (not shown) that are implemented in the row decoders (e.g., 104(1)-104(N) in FIG. 1), and each discharge assistance device (e.g., transistor 304 in FIG. 3) in each sense amplifier (e.g., 122(1)-122(M)) is selected to be the same size as each discharge transistor in each bit cell (e.g., transistor 206 in FIG. 2). By mimicking the driving and loading of the read word lines RWL, the discharge assistance circuitry accounts for the effects of PVT variations on the read word lines RWL.

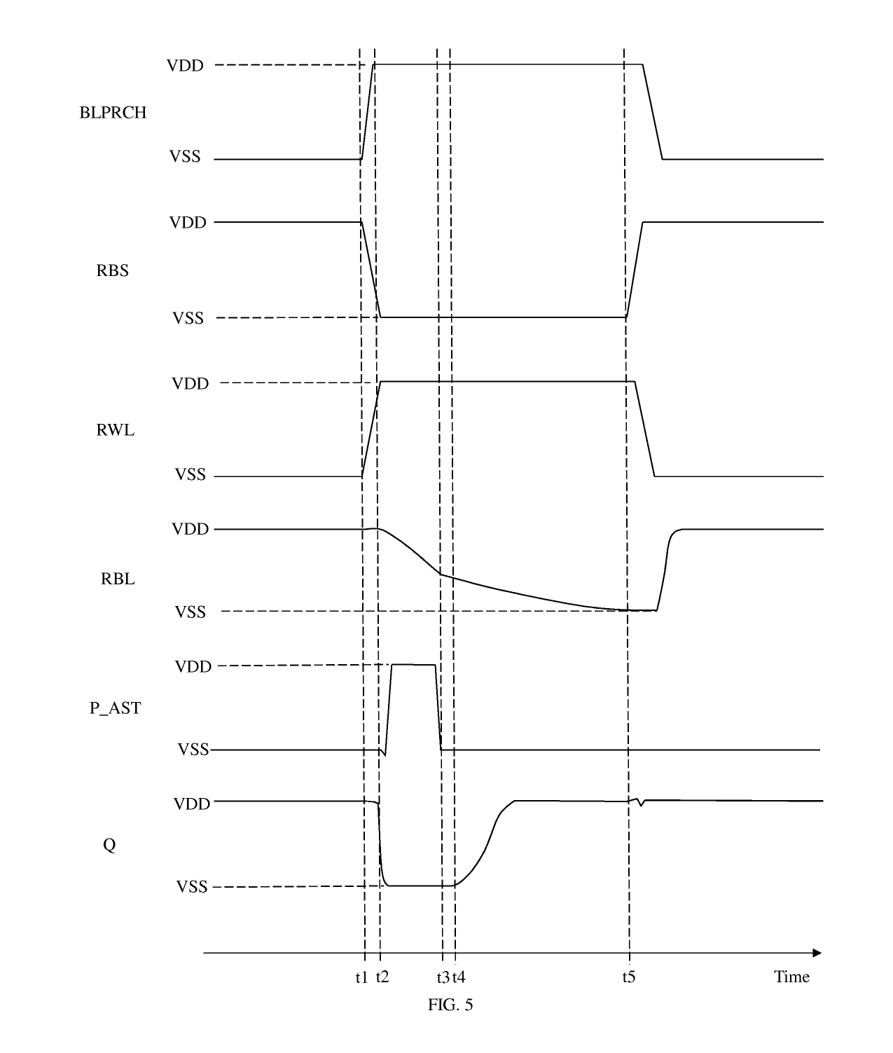

FIG. 5 shows an exemplary timing diagram of a read operation performed by memory device 100 to read a value of “1”. Prior to time t1, the bit-line pre-charge signal BLPRCH is low so that sense amplifiers 122(1)-122(M) pre-charge read bit lines RBL(1)-RBL(M). At time t1, the read operation is initiated by driving (i) the bit-line pre-charge signal BLPRCH high to terminate the pre-charging, (ii) the read bit-line select signal RBS low to initiate sensing of sense amplifiers 122(1)-122(M), and (iii) the read word line RWL high for the bit cell that is to be read.

At around time t2, the read bit line RBL begins to discharge, and, just after time t2, the pulse assist signal P_AST is driven high to enable discharge assistance. From the time that pulse assist signal P_AST is driven high to about time t3 (i.e., when P_AST signal is low), the read bit line RBL is discharged through both the bit cell (e.g., transistors 206 and 208 in FIG. 2) and the discharge assistance device (e.g., transistor 304 in FIG. 3) in the sense amplifier. As a result, the discharge rate of the read bit line RBL is faster between times t2 and t3 than it would be had discharge assistance not been applied.

At about time t4, the output Q of the sense amplifier begins to rise, indicating that the sense amplifier has detected that a value of “1” was stored in the bit cell. Note that, due to the increased discharge rate from times t2 to t3, the output Q of the sense amplifier begins to rise sooner than it would had discharge assistance not been applied. After time t5, the bit-line pre-charge signal BLPRCH, the read bit-line select signal RBS, the read word line RWL, and the read bit line RBL return to their pre-read states.

FIG. 6 shows an exemplary timing diagram of a read operation performed by memory device 100 to read a value of “0”. The timings of the bit-line pre-charge signal BLPRCH, the read bit-line select signal RBS, the read word-line signal RWL, and the pulse-assist signal P_AST are identical to those shown in FIG. 6. At about time t2, the pulse-assist signal P_AST transitions high such that the read bit line RBL begins to discharge. Note that the read bit line RBL discharges only through the discharge assistance device (e.g., transistor 304 in FIG. 3) in the sense amplifier and not through the bit cell since a value of “0” is stored in the bit cell. At about time t3, the pulse-assist signal P_AST transitions low to stop the discharging of the read bit line RBL. Due to the strength (i.e., size) of the discharge assistance device and the duration of the pulse applied to pulse-assist signal P_AST, the read bit line RBL only partially discharges and does not discharge to the trip point of the tri-state inverter in the sense amplifier (e.g., tri-state inverter 306 in FIG. 3). As a result, even though some discharge assistance is provided in this case, the tri-state inverter of the sense amplifier 306 keeps output signal Q low, indicating that that the sense amplifier has detected that a value of “0” was stored in the bit cell.

Although specific implementations of a bit cell, a sense amplifier, and a discharge assistance controller are illustrated in FIGS. 2-4, respectively, embodiments of the disclosure are not so limited. The bit cell, the sense amplifier, and the discharge assistance controller illustrated in FIGS. 2-4 are merely exemplary, and one of skilled in the art would recognize that these circuits may be implemented in other manners. For example, one skilled in the art would recognize that discharge assistance can be provided to memory arrays that employ ROM cells or RAM cells other than the RAM cell shown in FIG. 2.

While the exemplary embodiments of the disclosure have been described with respect to processes of circuits, including possible implementation as a single integrated circuit, a multi-chip module, a single card, or a multi-card circuit pack, the invention is not so limited.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

Although various signal were described as changing state from a high state to a low state and from a low state to a high state, those skilled in the art would understand that the states of such signals can be reversed. For example, in some embodiments, the read bit-line select signal RBS could start low before a read operation and go high when a read operation is initiated. In such embodiments, the circuitry of sense amplifier 300 and discharge assistance controller 400 would be modified to account for the reversed signal states. Such modifications may include using a logic circuit other than NOR gate 408 of FIG. 4, and changing N-type transistor 304 of FIG. 3 to a P-type transistor.

According to alternative embodiments of the disclosure, the discharge assistance device may be implemented using switching circuitry other than a single N-type transistor (e.g., transistor 304 of FIG. 3) that enables discharge assistance to be turned on and off.

Although embodiments of the disclosure were described as modifying a pulse assistance duration in response to capacitive loading of a dummy bit line, where the dummy bit line simulates loading of the bit lines in a memory array, embodiments of the disclosure are not so limited. In alternative embodiments of the disclosure, the pulse assistance duration can be modified in response to other loads, such as fixed MOS capacitance, extra metal capacitance, etc. In such embodiments, the fixed MOS capacitance, extra metal capacitance, etc. may simulate loading of the bit lines in the memory array.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Signals and corresponding nodes or ports may be referred to by the same name and are interchangeable for purposes here.

Transistors are typically shown as single devices for illustrative purposes. However, it is understood by those with skill in the art that transistors will have various sizes (e.g., gate width and length) and characteristics (e.g., threshold voltage, gain, etc.) and may consist of multiple transistors coupled in parallel to get desired electrical characteristics from the combination. Further, the illustrated transistors may be composite transistors.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. An apparatus comprising:
a memory array of memory cells arranged in at least one column that is coupled to a read bit line;
a discharge device coupled to the read bit line and configured to provide discharge assistance to the read bit line; and
a discharge assistance controller coupled to the discharge device and configured to modify duration of the discharge assistance in correlation with capacitance of the read bit line.

2. The apparatus of claim 1, further comprising a dummy bit line coupled to the discharge assistance controller, wherein:
capacitance of the dummy bit line correlates the with the capacitance of the read bit line; and
the discharge assistance controller is configured to modify the duration of the discharge assistance in correlation with the capacitance of the dummy bit line.

3. The apparatus of claim 2, wherein:
the discharge assistance controller is configured to pre-charge the dummy bit line;
the discharge assistance controller is configured to modify the duration of the discharge assistance in response to a discharge duration of the dummy bit line; and
the discharge duration of the dummy bit line correlates with the capacitance of the dummy bit line.

4. The apparatus of claim 1, wherein:
the discharge assistance controller is configured to generate a discharge assistance pulse in response to an input signal that identifies a beginning of a read operation, wherein the duration of the discharge assistance correlates with duration of the discharge assistance pulse; and
the discharge device activates the discharge assistance in response to the discharge assistance pulse.

5. The apparatus of claim 4, wherein the discharge assistance controller comprises:
a first path comprising at least one inverter configured to invert the input signal to generate an output signal; and
a logic gate configured to generate the discharge assistance pulse in response to the output signal and the input signal.

6. The apparatus of claim 5, wherein:
the first path is coupled to a dummy bit line such that generation of the inverted signal is delayed by discharging of the dummy bit line; and
the duration of the discharge assistance pulse is correlated with the delay in generating the output signal.

7. The apparatus of claim 4, wherein the discharge device is a transistor and the discharge assistance pulse is coupled to the gate of the transistor.

8. The apparatus of claim 1, wherein:
the memory cells in the at least one column are single-ended read bit cells; and
the apparatus further comprises at least one single-ended sense amplifier coupled to the read bit line.

9. The apparatus of claim 1, wherein:
the discharge device is coupled to the discharge assistance controller; and
loading between the discharge device and the discharge assistance controller is correlated with loading on a word line of the memory array.

10. A method for operating an apparatus comprising a memory array of memory cells arranged in at least one column that is coupled to a read bit line, wherein the method comprises:
(a) providing discharge assistance to the read bit line; and
(b) modifying duration of the discharge assistance in correlation with capacitance of the read bit line.
